(19) United States
(12) Patent Application Publication
(10) Pub. No.: US 2007/0109032 A1
(43) Pub. Date: May 17, 2007

(54) Charge pump circuit and method thereof

(75) Inventors: Moon-Sook Park, Seoul (KR); Kyu-Hyoun Kim, Suwon-si (KR)

Correspondence Address: HARNESS, DICKEY & PIERCE, P.L.C., P.O. BOX 8910, RESTON, VA, 20195, US

(73) Assignee: Samsung Electronics Co. Ltd.

(21) Appl. No.: 11/598,047

(22) Filed: Nov. 13, 2006

(30) Foreign Application Priority Data
Nov. 14, 2005 (KR) 10-2005-0108519

(51) Int. Cl. H03L 7/06

(52) U.S. Cl. 327/157

(57) ABSTRACT

A charge pump circuit and method thereof are provided. The example charge pump may include a first switch transistor supplying a first current to an output node in response to a first signal to increase a level of current at the output node, a second switch transistor sinking a second current from the output node in response to a second signal to decrease a level of current at the output node and a controller reducing an amount of the first and second currents if the first and second currents are generated concurrently. The example method may include supplying a first current to an output node in response to a first signal to increase a level of current at the output node, sinking a second current from the output node in response to a second signal to decrease a level of current at the output node and reducing an amount of the first and second currents if the first and second currents are generated concurrently.

### PRIORITY STATEMENT

This application claims the priority of Korean Patent Application No. 10-2005-0108519, filed on Nov. 14, 2005, in the Korean Intellectual Property Office, the disclosure of which is incorporated herein in its entirety by reference.

### BACKGROUND OF THE INVENTION

1. Field of the Invention

Example embodiments of the present invention relate generally to a charge pump circuit and method thereof, and more particularly to a charge pump circuit and method of controlling current.

2. Description of the Related Art

A conventional phase locked loop (PLL) circuit may include a phase detector, a charge pump circuit, a loop filter implemented as a low pass filter (LPF), and a voltage controlled oscillator (VCO). The phase detector may detect a phase difference between a reference clock signal and a feedback clock signal output from the VCO. The charge pump circuit may charge the loop filter with electric charges in response to an output signal of the phase detector or, alternatively, may discharge electric charges from the loop filter. The VCO may output the feedback clock signal, which may be synchronized (e.g., locked) with the reference clock signal, in response to a voltage corresponding to the electric charges that fill the loop filter. The charge pump circuit may alternatively be deployed within a delay locked loop (DLL) circuit.

FIG. 1 is circuit diagram illustrating a conventional charge pump circuit 100. Referring to FIG. 1, the charge pump circuit 100 may include constant current sources 105 and 135, PMOS transistors 110 and 115, a buffer 120 having a voltage gain is one, NMOS transistors 125 and 130 and inverters 140 and 145.

Referring to FIG. 1, the PMOS transistors 110 and 115 may perform a switching operation in response to up signals UP and /UP, respectively. The NMOS transistors 125 and 130 may perform a switching operation in response to down signals DN and /DN, respectively. The PMOS transistor 115 may source an up current lup to an output node 150 in response to the complementary up signal /UP. The NMOS transistor 130 may sink a down current ldn from the output node 150 in response to the down signal DN.

Referring to FIG. 1, the up signal UP may be generated if the phase of the reference clock signal input to a phase detector included in a PLL or DLL circuit leads (e.g., does not lag or follow) that of the feedback clock signal input to the phase detector. The complementary up signal /UP may be an inverted signal of the up signal UP. The down signal DN may be generated if the phase of the reference clock signal lags behind (e.g., does not lead) that of the feedback clock signal. The complementary down signal /DN may be an inverted signal of the down signal DN.

Referring to FIG. 1, the PMOS transistor 110, the NMOS transistor 125, and the buffer 120 may reduce switch noise generated during the switching operation. In other words, the PMOS transistor 110, the NMOS transistor 125, and the buffer 120 may reduce a charge sharing effect which may occur if the PMOS transistor 115 and the NMOS transistor 130 perform the switching operation.

FIG. 2 illustrates an operation of the charge pump circuit 100. In particular, in a first operation mode (1) of FIG. 2 a phase-lead condition in which the phase of the reference clock signal leads that of the feedback clock signal may be illustrated. In the first operation mode (1) of FIG. 2, a pulse width of the up signal UP may be greater than that of the down signal DN. A difference PW between the pulse widths of the up signal UP and the down signal DN may be proportional to the phase difference between the reference clock signal and the feedback clock signal. An output current lch output through an output terminal OUT may have a value obtained after the down current ldn is subtracted from the up current lup.

In a second operation mode (2) of FIG. 2, a phase-lag condition in which the phase of the reference clock signal lags behind that of the feedback clock signal may be illustrated. In the second operation mode (2) of FIG. 2, the charge pump circuit 100 may operate in a similar manner as in the phase-lead condition. In the second operation mode (2) of FIG. 2, an in-phase condition in which the phase of the reference clock signal may be substantially the same as that of the feedback clock signal may be illustrated. Accordingly, the up signal UP and the down signal DN may be activated concurrently (e.g., simultaneously), and the pulse width of the up signal UP may be substantially equal to that of the down signal DN. An output current lch output, through the output terminal OUT, may have a value obtained after the down current ldn is subtracted from the up current lup.

Referring to FIG. 2, a time interval during which the up current lup and the down current ldn may be concurrently generated (e.g., corresponding to the in-phase condition), the output current lch may not be precisely “0”, but rather may be offset from “0” based on a “mismatch” (e.g., temporal asymmetry) between the up current lup and the down current ldn. The offset may be caused by finite output resistance of a transistor, the charge sharing effect generated during the switching operation and/or a mismatch (e.g., unequal) of transistor sizes.

FIG. 3 is a circuit diagram illustrating another conventional charge pump circuit 200. Referring to FIG. 3, the charge pump circuit 200 may include PMOS transistors 205 and 210, NMOS transistors 215, 220, 225 and 230 and constant current sources 235 and 240.

Referring to FIG. 3, the NMOS transistor 220, which may operate in response to an up signal UP, may control an up current lup to be sourced to an output node 245. The NMOS transistor 230, which may operate in response to the down signal DN, may control a down current ldn to sink from the output node 245. Because the up signal UP and the down signal DN of FIG. 3 may correspond to those illustrated in FIG. 1, a further detailed description thereof has been omitted for the sake of brevity.

FIG. 4 illustrates an operation of the charge pump circuit 200 of FIG. 3. Referring to FIG. 4, a first operation (1) may illustrate the phase-lead condition, in which the phase of the reference clock signal leads that of the feedback clock signal. In the first operation (1) of FIG. 4, a pulse width of the up signal UP may be greater that that of the down signal DN. A difference PW between the pulse widths of the up signal UP and the down signal DN may be proportional to the phase difference between the reference clock signal and the feedback clock signal. An output current lch output through an output terminal OUT may have a value obtained by subtracting the down current ldn from the up current lup.

Referring to FIG. 4, a second operation (2) may illustrate the phase-lag condition, in which the phase of the reference clock signal lags behind that of the feedback clock signal, and the charge pump circuit 200 may operate in a similar manner as in the phase-lead condition. In the second operation (2) of FIG. 4, the phase of the reference clock signal may be identical to that of the feedback clock signal, the up signal UP and the down signal DN may be activated at the same time, and the pulse width of the up signal UP may be equal to that of the down signal DN. An output current lch output through the output terminal OUT may have a value obtained by subtracting the down current ldn from the up current lup.

Referring to FIG. 4, a time interval may occur where the up current lup and the down current ldn are concurrently (e.g., simultaneously) generated or “active” (e.g., with the time interval corresponding to the in-phase condition). However, similar to FIG. 2, the output current lch may not be precisely “0”, but rather may be offset from “0” based on a “mismatch” (e.g., temporal asymmetry) between the up current Iup and the down current Idn. The offset may be caused by finite output resistance of a transistor, the charge sharing effect generated during the switching operation and/or a mismatch (e.g., unequal) of transistor sizes.

### SUMMARY OF THE INVENTION

An example embodiment of the present invention is directed to a charge pump circuit, including a first switch transistor supplying a first current to an output node in response to a first signal to increase a level of current at the output node, a second switch transistor sinking a second current from the output node in response to a second signal to decrease a level of current at the output node and a controller reducing an amount of the first and second currents if the first and second currents are generated concurrently.

Another example embodiment of the present invention is directed to a method of controlling current, including supplying a first current to an output node in response to a first signal to increase a level of current at the output node, sinking a second current from the output node in response to a second signal to decrease a level of current at the output node and reducing an amount of the first and second currents if the first and second currents are generated concurrently.

### BRIEF DESCRIPTION OF THE DRAWINGS

The accompanying drawings are included to provide a further understanding of the invention, and are incorporated in and constitute a part of this specification. The drawings illustrate example embodiments of the present invention and, together with the description, serve to explain principles of the present invention.

FIG. 1 is circuit diagram illustrating a conventional charge pump circuit.

FIG. 2 illustrates an operation of the charge pump circuit.

FIG. 3 is a circuit diagram illustrating another conventional charge pump circuit.

FIG. 4 illustrates an operation of the charge pump circuit of FIG. 3.

FIG. 5 is a circuit diagram illustrating a charge pump circuit according to an example embodiment of the present invention.

FIG. 6 illustrates an operation of the charge pump circuit of FIG. 5 according to another example embodiment of the present invention.

FIG. 7 is a circuit diagram illustrating a charge pump circuit according to another example embodiment of the present invention.

FIG. 8 is a circuit diagram illustrating a charge pump circuit according to another example embodiment of the present invention.

FIG. 9 is a circuit diagram illustrating a charge pump circuit according to another example embodiment of the present invention.

FIG. 10 is a block diagram illustrating a phase locked loop (PLL) circuit including a charge pump circuit according to an example embodiment of the present invention.

FIG. 11 is a block diagram illustrating a delay locked loop (DLL) circuit including a charge pump circuit according to an example embodiment of the present invention.

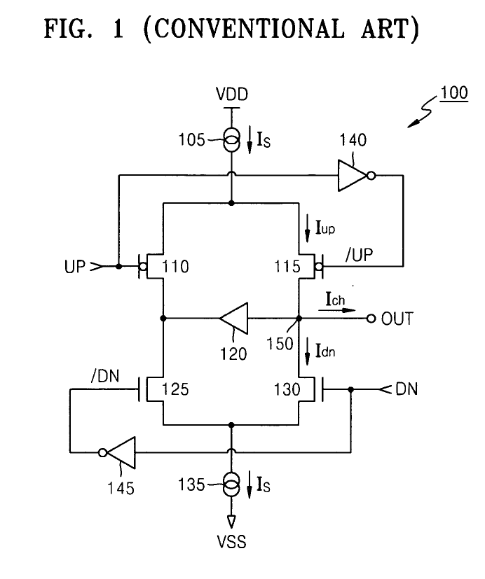

### DETAILED DESCRIPTION OF EXAMPLE EMBODIMENTS OF THE PRESENT INVENTION

Detailed illustrative example embodiments of the present invention are disclosed herein. However, specific structural and functional details disclosed herein are merely representative for purposes of describing example embodiments of the present invention. Example embodiments of the present invention may, however, be embodied in many alternate forms and should not be construed as limited to the embodiments set forth herein.

Accordingly, while example embodiments of the invention are susceptible to various modifications and alternative forms, specific embodiments thereof are shown by way of example in the drawings and will herein be described in detail. It should be understood, however, that there is no intent to limit example embodiments of the invention to the particular forms disclosed, but conversely, example embodiments of the invention are to cover all modifications, equivalents, and alternatives falling within the spirit and scope of the invention. Like numbers may refer to like elements throughout the description of the figures.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the present invention. As used herein, the term “and/or” includes any and all combinations of one or more of the associated listed items.

It will be understood that when an element is referred to as being “connected” or “coupled” to another element, it can be directly connected or coupled to the other element or intervening elements may be present. Conversely, when an element is referred to as being “directly connected” or “directly coupled” to another element, there are no intervening elements present. Other words used to describe the relationship between elements should be interpreted in a like fashion (e.g., “between” versus “directly between”, “adjacent” versus “directly adjacent”, etc.).

The terminology used herein is for the purpose of describing particular embodiments only and is not intended to be limiting of example embodiments of the invention. As used herein, the singular forms “a”, “an” and “the” are intended to include the plural forms as well, unless the context clearly indicates otherwise. It will be further understood that the terms “comprises”, “comprising”, “includes” and/or “including”, when used herein, specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

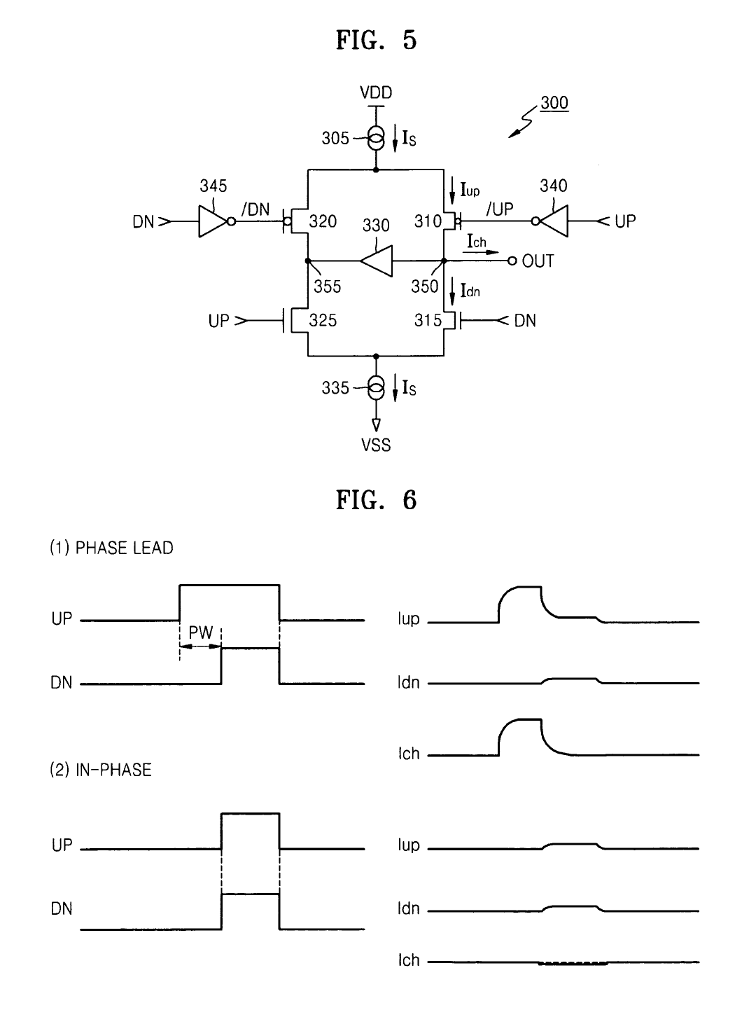

FIG. 5 is a circuit diagram illustrating a charge pump circuit 300 according to an example embodiment of the present invention. In the example embodiment of FIG. 5, the charge pump circuit 300 may include first and second current sources 305 and 335 (e.g., constant current sources), first through fourth switch transistors 310, 315, 320 and 325, a buffer 330 with a given voltage gain (e.g., one) and inverters 340 and 345. An up signal UP and a down signal DN may be input to the charge pump circuit 300. The up signal UP may be generated if a phase of a reference clock signal input to a phase detector included in a phase locked loop (PLL) or delay locked loop (DLL) circuit leads that of a feedback clock signal input to the phase detector. The down signal DN may be generated if the phase of the reference clock signal lags behind that of the feedback clock signal.

In the example embodiment of FIG. 5, the first switch transistor 310 may source an up current lup to an output node 350 in response to the up signal UP. The up current lup may be provided by the first current source 305. The first current source 305 may supply a current equal to ls. For example, the first switch transistor 310 may operate if an inverted up signal /UP, which may be obtained after the inverter 340 inverts the up signal UP, is activated. In an example, the first switch transistor 310 may be a PMOS transistor.

In the example embodiment of FIG. 5, the second switch transistor 315 may sink the down current ldn from the output node 350 in response to the down signal DN. The down current ldn may be provided by the second current source 335. The second current source 335 may supply a current equal to ls. In an example, the second switch transistor 315 may be an NMOS transistor.

In the example embodiment of FIG. 5, the third switch transistor 320, the fourth switch transistor 325 and the buffer 330 may be included within a controller. If the up current lup and the down current ldn are generated concurrently (e.g., simultaneously), the controller may reduce an amount of the up current lup and the down current ldn in response to the up signal UP and the down signal DN. In an example, the condition in which the up current lup and the down current ldn are generated concurrently (e.g., simultaneously) may correspond to a condition in which the phase of the reference clock signal is substantially the same as that of the feedback clock signal.

In the example embodiment of FIG. 5, the third switch transistor 320 may control a portion of the current ls of the first current source 305, which may provide the up current lup, so as to flow to an internal node 355 in response to the down signal DN. In an example, the third switch transistor 320 may control a portion of the current ls, provided by the first current source 305, so as to flow to the internal node 355 if an inverted signal /DN, which may be obtained after the inverter 345 inverts the down signal DN, is activated. Thus, the third switch transistor 320 may reduce the up current lup if the up current lup and the down current ldn are generated concurrently (e.g., simultaneously).

In the example embodiment of FIG. 5, the third switch transistor 320 may be larger than the first switch transistor 310. Because a channel width in the third switch transistor 320 may be greater than that of a channel width in the first switch transistor 310, a higher amount of current may flow through the third switch transistor 320 than the first switch transistor 310. In an example, the third switch transistor 320 may be a PMOS transistor.

In the example embodiment of FIG. 5, the fourth switch transistor 325 may provide a portion of the current ls of the second current source 335, which may provide the down current ldn, to the second current source 335 in response to the up signal UP. For example, the fourth switch transistor 325 may provide a portion of the current ls to the second current source 335 if the up signal UP is activated (e.g., set to one of a first logic level and a second logic level, such as a higher logic level and a lower logic level, respectively). Thus, the fourth switch transistor 325 may reduce the down current ldn if the up current lup and the down current ldn are generated concurrently (e.g., simultaneously).

In the example embodiment of FIG. 5, the fourth switch transistor 325 may be larger than the second switch transistor 315. Because a channel width in the fourth switch transistor 325 may be greater than that of a channel width in the second switch transistor 315, a higher amount of current may flow through the fourth switch transistor 325 than the second switch transistor 315. In an example, the fourth switch transistor 325 may be an NMOS transistor.

In the example embodiment of FIG. 5, if the up current lup and the down current ldn are generated concurrently (e.g., simultaneously), a current level of the up current lup and the down current ldn may be reduced using the third switch transistor 320, which may operate in response to the down signal DN, and the fourth switch transistor 325, which may operate in response to the up signal UP. Accordingly, an offset of an output current lch output through an output terminal OUT, which may be a value obtained by subtracting the down current ldn from the up current lup, may be reduced.

In the example embodiment of FIG. 5, the buffer 330 may include an input terminal connected to the output node 350 and an output terminal connected to the internal node 355. The buffer 330, the third switch transistor 320, and the fourth switch transistor 325 may reduce switch noise generated during a switching operation. For example, the buffer 330, the third switch transistor 320 and the fourth switch transistor 325 may reduce a charge sharing effect which may occur if the first switch transistor 310 and the second switch transistor 315 perform the switching operation.

FIG. 6 illustrates an operation of the charge pump circuit 300 of FIG. 5 according to another example embodiment of the present invention.

In the example embodiment of FIG. 6, a first operation (1) may refer to a phase-lead condition, in which the phase of the reference clock signal leads that of the feedback clock signal. In the first operation (1) of the example embodiment of FIG. 6, a pulse width of the up signal UP may be greater that that of the down signal DN. A difference PW between the pulse widths of the up signal UP and the down signal DN may be proportional to the phase difference between the reference clock signal and the feedback clock signal. An output current lch output through the output terminal OUT may have a value obtained by subtracting the down current ldn from the up current lup.

In the example embodiment of FIG. 6, a second operation (2) may refer to a phase-lag condition in which the phase of the reference clock signal lags behind that of the feedback signal. It will be assumed that the charge pump circuit 300, in the second operation (2) (e.g., the phase-lag condition), may operate in a similar manner as that of the first operation (1) (e.g., the phase-lead condition).

In the example embodiment of FIG. 6, in the second operation (2), the phase of the reference clock signal may be substantially the same as that of the feedback clock signal. The up signal UP and the down signal DN may be activated concurrently (e.g., simultaneously), and the pulse width of the up signal UP may be substantially equal to that of the down signal DN. An output current lch output through the output terminal OUT may have a value obtained by subtracting the down current ldn from the up current lup.

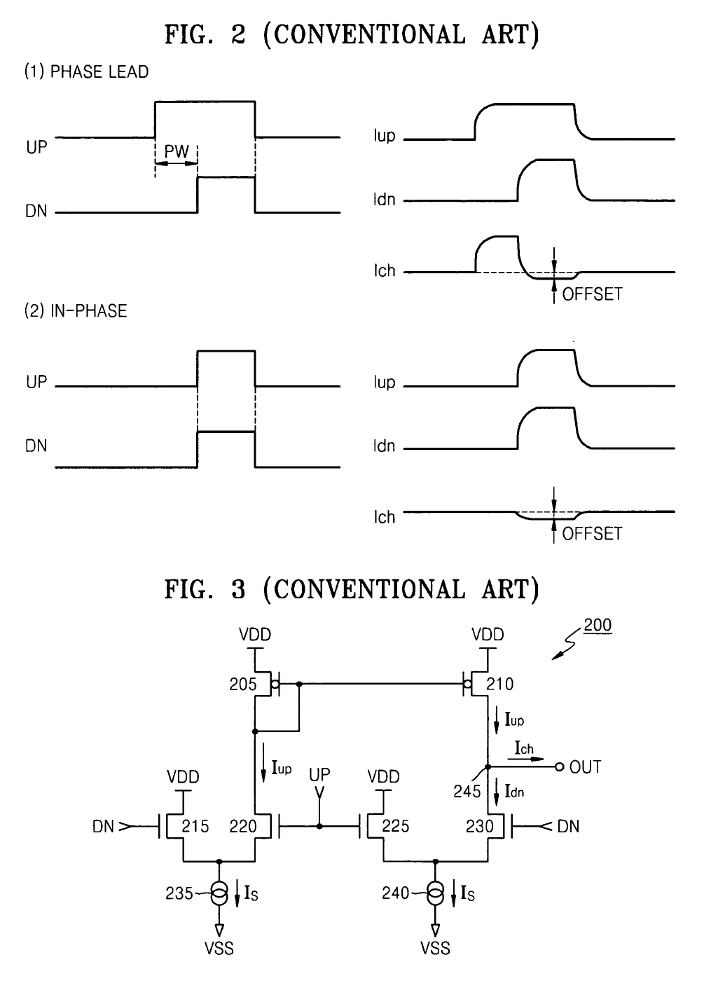

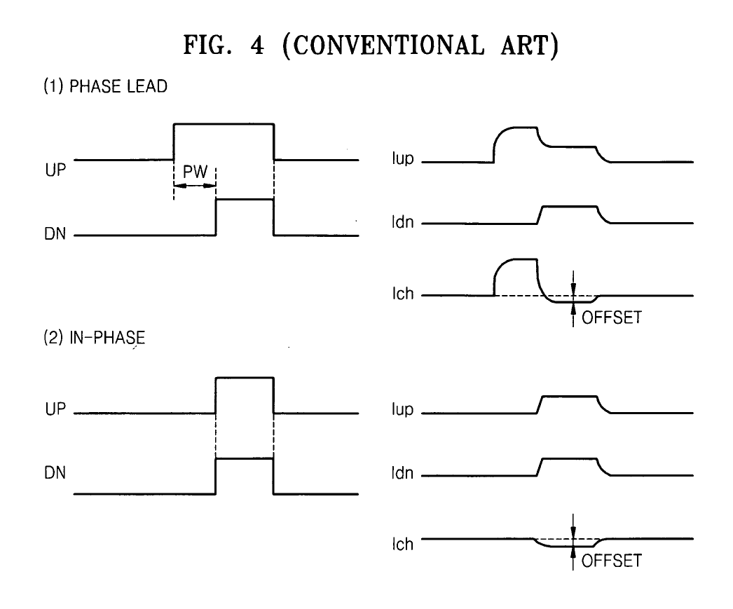

In the example embodiment of FIG. 6, in a time interval during which the up current lup and the down current ldn are concurrently generated (e.g., wherein the time interval corresponds to the in-phase condition) (e.g., in either of the first operation (1) or the second operation (2)), the output current lch may not be precisely “0”, but rather may have a relatively low offset. In an example, the relatively low offset associated with the example embodiments of FIGS. 5 and 6 may be smaller than the offset associated with the conventional output current lch illustrated in FIGS. 2 and 4, as discussed in the Background of the Invention. The smaller offset, associated with the example embodiments of FIGS. 5 and 6, may reduce noise generated in an output of the PLL circuit and/or the DLL circuit.

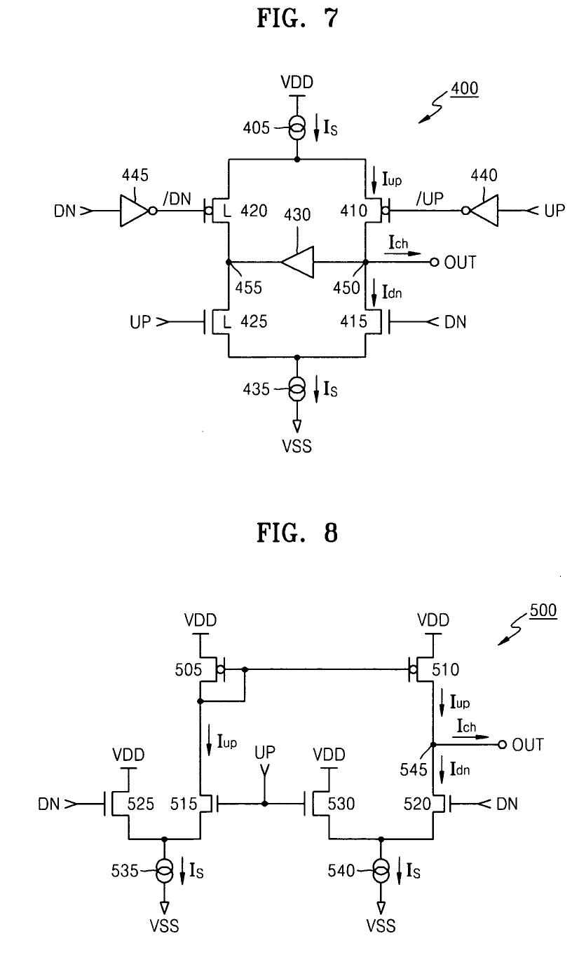

FIG. 7 is a circuit diagram illustrating a charge pump circuit 400 according to another example embodiment of the present invention.

In the example embodiment of FIG. 7, the charge pump circuit 400 may include first and second current sources 405 and 435 (e.g., constant current sources), first through fourth switch transistors 410, 415, 420 and 425, a buffer 430 with a given voltage gain (e.g., one) and inverters 440 and 445. An up signal UP and a down signal DN may be input to the charge pump circuit 400. The up signal UP may be generated if a phase of a reference clock signal input to a phase detector included in a PLL circuit or DLL circuit leads that of a feedback clock signal input to the phase detector. The down signal DN may be generated if the phase of the reference clock signal lags behind that of the feedback clock signal.

In the example embodiment of FIG. 7, the first switch transistor 410 may source (e.g., supply) an up current lup to an output node 450 in response to the up signal UP. The up current lup may be provided by the first current source 405 (e.g., with a current level equal to ls). In an example, the first switch transistor 410 may operate (e.g., be active or turned on) if an inverted up signal /UP, which may be obtained after the inverter 440 inverts the up signal UP, may be activated (e.g., set to the first logic level). In an example, the first switch transistor 410 may be a PMOS transistor.

In the example embodiment of FIG. 7, the second switch transistor 415 may sink the down current ldn from the output node 450 in response to the down signal DN. The down current ldn may be provided by the second current source 435 (e.g., with a current level equal to ls). In an example, the second switch transistor 415 may be an NMOS transistor.

In the example embodiment of FIG. 7, the third switch transistor 420, the fourth switch transistor 425 and the buffer 430 may be included within a controller. If the up current lup and the down current ldn are generated concurrently (e.g., simultaneously), the controller may reduce a current level of the up current lup and the down current ldn in response to the up signal UP and the down signal DN. In an example, a condition in which the up current lup and the down current ldn are generated concurrently (e.g., simultaneously) may correspond to a condition in which the phase of the reference clock signal may be substantially the same as that of the feedback clock signal.

In the example embodiment of FIG. 7, the third switch transistor 420 may control a portion of the current ls of the first current source 405, which may provide the up current lup, to flow to an internal node 455 in response to the down signal DN. For example, the third switch transistor 420 may control a portion of the current ls if an inverted signal /DN, which may be obtained after the inverter 445 inverts the down signal DN, may be activated. Thus, the third switch transistor 420 may reduce the up current lup if the up current lup and the down current ldn are generated concurrently (e.g., simultaneously).

In the example embodiment of FIG. 7, a threshold voltage of the third switch transistor 420 may be greater than that of the first switch transistor 410. Therefore, a higher amount of current may flow through the third switch transistor 420 than the first switch transistor 410. In an example, the third switch transistor 420 may be a PMOS transistor.

In the example embodiment of FIG. 7, the fourth switch transistor 425 may provide a portion of the current ls of the second current source 435, which may provide the down current ldn, to the second current source 435 in response to the up signal UP. For example, the fourth switch transistor 425 may provide a portion of the current ls if the up signal UP is activated (e.g., set to a first logic level, such as a higher logic level or logic “1”, or a second logic level, such as a lower logic level or logic “0”). Thus, the fourth switch transistor 425 may reduce the down current ldn if the up current lup and the down current ldn are generated concurrently (e.g., simultaneously).

In the example embodiment of FIG. 7, a threshold voltage of the fourth switch transistor 425 may be lower than that of the second switch transistor 415. Therefore, a higher amount of current may flow through the fourth switch transistor 425 than the second switch transistor 415. In an example, the fourth switch transistor 425 may be an NMOS transistor.

In the example embodiment of FIG. 7, if the up current lup and the down current ldn are generated concurrently (e.g., simultaneously), a current level of the up current lup and the down current ldn may be reduced using the third switch transistor 420, which may operate in response to the down signal DN, and the fourth switch transistor 425, which may operate in response to the up signal UP. Accordingly, an offset of an output current lch output through an output terminal OUT, which may be a value obtained by subtracting the down current ldn from the up current lup, may be reduced.

In the example embodiment of FIG. 7, the buffer 430 may include an input terminal connected to the output node 450 and an output terminal connected to the internal node 455. The buffer 430, the third switch transistor 420, and the fourth switch transistor 425 may reduce (e.g., minimize) noise generated during the switching operation. For example, the buffer 430, the third switch transistor 420, and the fourth switch transistor 425 may reduce the charge sharing effect, which may occur if the first switch transistor 410 and the second switch transistor 415 perform the switching operation. Because the operation of the charge pump circuit 400 may be substantially the same as that of the charge pump circuit 300 illustrated in FIG. 6, a further detailed description thereof will be omitted for the sake of brevity.

FIG. 8 is a circuit diagram illustrating a charge pump circuit 500 according to another example embodiment of the present invention. In the example embodiment of FIG. 8, the charge pump circuit 500 may include PMOS transistors 505 and 510 (e.g., configured so as to form a current mirror circuit), first through fourth switch transistors 515, 520, 525 and 530, and first and second current sources 535 and 540 (e.g., constant current sources). An up signal UP and a down signal DN may be input to the charge pump circuit 500. The up signal UP may be generated if a phase of a reference clock signal input to a phase detector included in a PLL circuit or DLL circuit leads that of a feedback clock signal input to the phase detector. The down signal DN may be generated if the phase of the reference clock signal lags behind that of the feedback clock signal.

In the example embodiment of FIG. 8, the first switch transistor 515 may source (e.g., supply) an up current lup to an output node 545 in response to the up signal UP. The up current lup may be provided by the first current source 535 (e.g., having a current level equal to ls). In an example, the first switch transistor 515 may be an NMOS transistor.

In the example embodiment of FIG. 8, the second switch transistor 520 may sink the down current ldn from the output node 545 in response to the down signal DN. The down current ldn may be provided by the second current source 540 (e.g., having a current level equal to ls). In an example, the second switch transistor 520 may be an NMOS transistor.

In the example embodiment of FIG. 8, the third switch transistor 525 and the fourth switch transistor 530 may be included within a controller. If the up current lup and the down current ldn are generated concurrently (e.g., simultaneously), the controller may reduce a current level of the up current lup and the down current ldn in response to the up signal UP and the down signal DN. In an example, the condition in which the up current lup and the down current ldn are generated concurrently (e.g., simultaneously) may correspond to a condition in which the phase of the reference clock signal may be substantially equal to that of the feedback clock signal.

In the example embodiment of FIG. 8, the third switch transistor 525 may provide a portion of the current ls of the first current source 535, which may provide the up current lup, in response to the down signal DN. For example, the third switch transistor 525 may provide a portion of the current ls if the down signal DN is activated (e.g., set to the first logic level, such as a higher logic level or logic “1”). Thus, the third switch transistor 535 may reduce the up current lup if the up current lup and the down current ldn are generated concurrently (e.g., simultaneously).

In the example embodiment of FIG. 8, the third switch transistor 525 may be larger than the first switch transistor 515. Therefore, because a channel width in the third switch transistor 525 may be greater than that of a channel width in the first switch transistor 515, a higher amount of current may flow through the third switch transistor 525 than the first switch transistor 515. In an example, the third switch transistor 525 may be an NMOS transistor.

In the example embodiment of FIG. 8, the fourth switch transistor 530 may provide a portion of the current ls of the second current source 540, which may provide the down current ldn, to the second current source 540 in response to the up signal UP. For example, the fourth switch transistor 530 may provide a portion of the current ls if the up signal UP is activated (e.g., set to the first logic level, such as a higher logic level or logic “1”). Thus, the fourth switch transistor 530 may reduce the down current ldn if the up current lup and the down current ldn are generated concurrently (e.g., simultaneously).

In the example embodiment of FIG. 8, the fourth switch transistor 530 may be larger than the second switch transistor 520. Therefore, because a channel width in the fourth switch transistor 530 may be greater than that of a channel width in the second switch transistor 520, a higher amount of current may flow through the fourth switch transistor 530 than the second switch transistor 520. In an example, the fourth switch transistor 530 may be an NMOS transistor.

In the example embodiment of FIG. 8, if the up current lup and the down current ldn are generated concurrently (e.g., simultaneously), a current level of the up current lup and the down current ldn may be reduced using the third switch transistor 525, which may operate in response to the down signal DN, and the fourth switch transistor 530, which may operate in response to the up signal UP. Accordingly, an offset of an output current lch output through an output terminal OUT, which may be a value obtained by subtracting the down current ldn from the up current lup, may be reduced. Because the operation of the charge pump circuit 500 may be substantially the same as that of the charge pump circuit 300 illustrated in FIG. 6, a further detailed description thereof will be omitted for the sake of brevity.

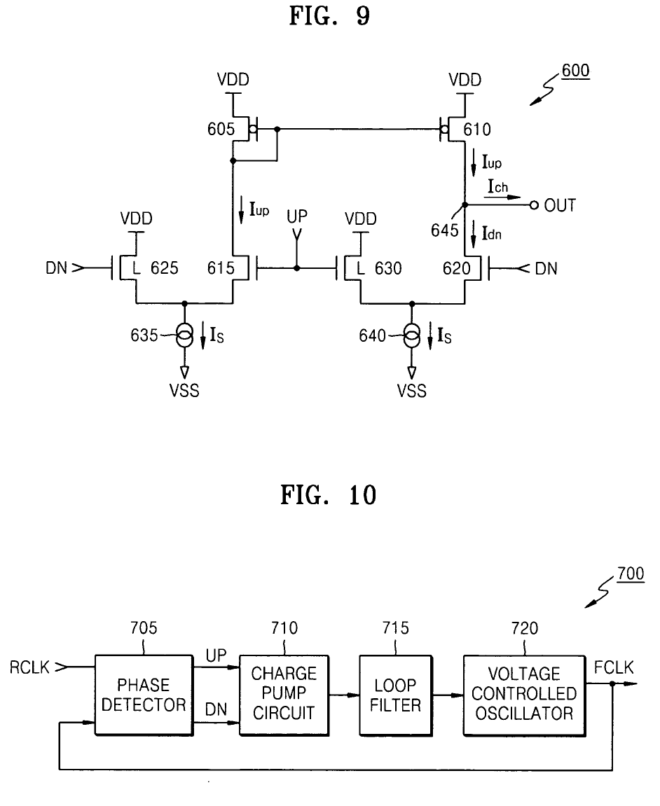

FIG. 9 is a circuit diagram illustrating a charge pump circuit 600 according to another example embodiment of the present invention. In the example embodiment of FIG. 9, the charge pump circuit 600 may include PMOS transistors 605 and 610 (e.g., which may form a current mirror circuit), first through fourth switch transistors 615, 620, 625 and 630, and first and second current sources 635 and 640 (e.g., constant current sources). An up signal UP and a down signal DN may be input to the charge pump circuit 600. The up signal UP may be generated if a phase of a reference clock signal input to a phase detector included in a PLL circuit or DLL circuit leads that of a feedback clock signal input to the phase detector. The down signal DN may be generated if the phase of the reference clock signal lags behind that of the feedback clock signal.

In the example embodiment of FIG. 9, the first switch transistor 615 may source (e.g., supply) an up current lup to an output node 645 in response to the up signal UP. The up current lup may be provided by the first current source 635 (e.g., having a current level equal to ls). In an example, the first switch transistor 615 may be an NMOS transistor.

In the example embodiment of FIG. 9, the second switch transistor 620 may sink the down current ldn from the output node 645 in response to the down signal DN. The down current ldn may be provided by the second current source 640 (e.g., having a current level equal to ls). In an example, the second switch transistor 620 may be an NMOS transistor.

In the example embodiment of FIG. 9, the third switch transistor 625 and the fourth switch transistor 630 may be included within a controller. If the up current lup and the down current ldn are generated concurrently (e.g., simultaneously), the controller may reduce a current level of the up current lup and the down current ldn in response to the up signal UP and the down signal DN. In example, a condition in which the up current lup and the down current ldn are generated concurrently (e.g., simultaneously) may correspond to a condition in which the phase of the reference clock signal may be substantially the same as that of the feedback clock signal.

In the example embodiment of FIG. 9, the third switch transistor 625 may provide a portion of the current ls of the first current source 635, which may provide the up current lup, in response to the down signal DN. For example, the third switch transistor 625 may provide a portion of the current ls if the down signal DN is activated (e.g., set to the first logic level, such as a higher logic level or logic “1”). Therefore, the third switch transistor 635 may reduce the up current lup if the up current lup and the down current ldn are generated concurrently (e.g., simultaneously).

In the example embodiment of FIG. 9, a threshold voltage of the third switch transistor 625 may be lower than that of the first switch transistor 615. Therefore, a larger amount of current may flow through the third switch transistor 625 than the first switch transistor 625. In an example, the third switch transistor 625 may be an NMOS transistor.

In the example embodiment of FIG. 9, the fourth switch transistor 630 may provide a portion of the current ls of the second current source 640, which may provide the down current ldn, to the second current source 640 in response to the up signal UP. For example, the fourth switch transistor 630 may provide a portion of the current ls if the up signal UP is activated. Thus, the fourth switch transistor 630 may reduce the down current ldn if the up current lup and the down current ldn are generated concurrently (e.g., simultaneously).

In the example embodiment of FIG. 9, a threshold voltage of the fourth switch transistor 630 may be lower than that of the second switch transistor 620. Therefore, a larger amount of current may flow through the fourth switch transistor 630 than the second switch transistor 620. In an example, the fourth switch transistor 630 may be an NMOS transistor.

In the example embodiment of FIG. 9, if the up current lup and the down current ldn are generated concurrently (e.g., simultaneously), a current level of the up current lup and the down current ldn may be reduced using the third switch transistor 625, which may operate in response to the down signal DN, and the fourth switch transistor 630, which may operate in response to the up signal UP. Accordingly, an offset of an output current lch output through an output terminal OUT, which may be a value obtained subtracting the down current ldn from the up current lup, may be reduced. Further, because the operation of the charge pump circuit 600 may be substantially the same as that of the charge pump circuit 300 illustrated in FIG. 6, a further detailed description thereof will be omitted for the sake of brevity.

FIG. 10 is a block diagram illustrating a PLL circuit 700 including a charge pump circuit 710 according to an example embodiment of the present invention. In the example embodiment of FIG. 10, the PLL circuit 700 may include a phase detector 705, the charge pump circuit 710, a loop filter 715 and a voltage controlled oscillator (VCO) 720.

In the example embodiment of FIG. 10, the phase detector 705 may generate an up signal UP if a phase of a reference clock signal RCLK leads that of a feedback clock signal FCLK and, alternatively, may generate a down signal DN if the phase of the reference clock signal RCLK lags behind that of the feedback clock signal FCLK.

In the example embodiment of FIG. 10, the charge pump circuit 710 may include any of the example charge pump circuits 300, 400, 500 and/or 600, which are described above in detail. The charge pump circuit 710 may source (e.g., supply) an up current to an output node connected to an output terminal in response to the up signal UP, and may alternatively sink a down current from the output node in response to the down signal DN. If the up current and the down current are generated concurrently (e.g., simultaneously), the charge pump circuit 710 may reduce an amount of the up current and the down current in response to the up signal UP and the down signal DN. In an example, a condition in which the up current and the down current are generated concurrently (e.g., simultaneously) may correspond to a condition in which the phase of the reference clock signal RCLK is substantially the same as that of the feedback clock signal FCLK.

In the example embodiment of FIG. 10, the loop filter 715 may low-pass-filter a voltage of the output terminal of the charge pump circuit 710 and may generate a control voltage (e.g., a direct current (DC) voltage). The VCO 720 may generate the feedback clock signal FCLK, which may be synchronized with the reference clock signal RCLK, in response to the control voltage of the loop filter 715.

In the example embodiment of FIG. 10, because the PLL circuit 700 includes the charge pump circuit 710, which may reduce the offset of an output current if the up current and the down current are generated concurrently (e.g., simultaneously), noise of the feedback clock signal FCLK, output from the VCO 720, may be reduced.

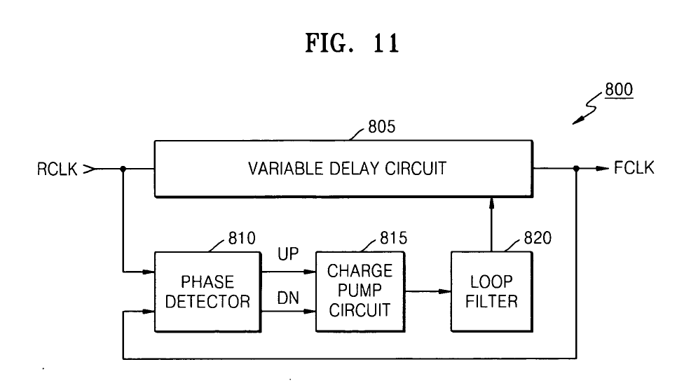

FIG. 11 is a block diagram illustrating a DLL circuit 800 including a charge pump circuit 815 according to an example embodiment of the present invention. In the example embodiment of FIG. 11, the DLL circuit 800 may include a variable delay circuit 805, a phase detector 810, the charge pump circuit 815 and a loop filter 820.

In the example embodiment of FIG. 11, the phase detector 810 may generate an up signal UP if a phase of a reference clock signal RCLK leads that of a feedback clock signal FCLK and, alternatively, may generate a down signal DN if the phase of the reference clock signal RCLK lags behind that of the feedback clock signal FCLK.

In the example embodiment of FIG. 11, the charge pump circuit 815 may include any of the charge pump circuits 300, 400, 500 and/or 600, which are described above in detail. The charge pump circuit 815 may source (e.g., supply) an up current to an output node connected to an output terminal in response to the up signal UP, and alternatively may sink a down current from the output node in response to the down signal DN. If the up current and the down current are generated concurrently (e.g., simultaneously), the charge pump circuit 815 may reduce a current level of the up current and the down current in response to the up signal UP and the down signal DN. In an example, a condition in which the up current and the down current are generated concurrently (e.g., simultaneously) may correspond to a condition in which the phase of the reference clock signal RCLK is substantially the same as that of the feedback clock signal FCLK.

In the example embodiment of FIG. 11, the loop filter 820 may low-pass-filter a voltage of the output terminal of the charge pump circuit 815 and may generate a control voltage (e.g., a DC voltage). The variable delay circuit 805 may delay the reference clock signal RCLK and may generate the feedback clock signal FCLK, which may be synchronized with the reference clock signal RCLK, in response to the control voltage. Because the DLL circuit 800 may include the charge pump circuit 815, which may reduce the offset of an output current if the up current and the down current are generated concurrently (e.g., simultaneously), noise of the feedback clock signal FCLK, output from the variable delay circuit 805, may be reduced.

Example embodiments of the present invention being thus described, it will be obvious that the same may be varied in many ways. For example, while the example embodiments of charge pump circuits are above described as being deployed within PLL circuits and DLL circuits, it will be appreciated that other example embodiments of the present invention may be directed to charge pump circuits deployed within any well-known electronic device. Further, it is understood that the above-described first and second logic levels may correspond to a higher level and a lower logic level, respectively, in an example embodiment of the present invention. Alternatively, the first and second logic levels/states may correspond to the lower logic level and the higher logic level, respectively, in other example embodiments of the present invention.

Such variations are not to be regarded as a departure from the spirit and scope of example embodiments of the present invention, and all such modifications as would be obvious to one skilled in the art are intended to be included within the scope of the following claims.

What is claimed is:

1. A charge pump circuit, comprising:
a first switch transistor supplying a first current to an output node in response to a first signal to increase a level of current at the output node;
a second switch transistor sinking a second current from the output node in response to a second signal to decrease a level of current at the output node; and
a controller reducing an amount of the first and second currents if the first and second currents are generated concurrently.

2. The charge pump circuit of claim 1, wherein the first signal is generated if a phase of a reference clock signals leads that of a feedback clock signal and the second signal is generated if the phase of the reference clock signal lags that of the feedback clock signal.

3. The circuit of claim 1, wherein the controller includes:
a third switch transistor controlling a portion of a current of a first current source, the first current source providing the first current, to flow to an internal node in response to the second signal;
a fourth switch transistor providing a portion of a current of a second current source, the second current source providing the second current, to the second current source in response to the first signal; and
a buffer including an input terminal connected to the output node and an output terminal connected to the internal node, the internal node positioned between the third and fourth switch transistors.

4. The circuit of claim 3, wherein a channel width of the third switch transistor is greater than that of the first switch transistor, and a channel width of the fourth switch transistor is greater than that of the second switch transistor.

5. The circuit of claim 3, wherein a threshold voltage of the third switch transistor is lower than that of the first switch transistor, and a threshold voltage of the fourth switch transistor is lower than that of the second switch transistor.

6. The circuit of claim 1, wherein the controller includes:
a third switch transistor controlling a portion of a current of a first current source, the first current source providing the first current, to the first current source in response to the second signal;
a fourth switch transistor providing a portion of a current of a second current source, the second current source providing the second current, to the second current source in response to the first signal.

7. The circuit of claim 6, wherein a channel width of the third switch transistor is greater than that of the first switch transistor, and a channel width of the fourth switch transistor is greater than that of the second switch transistor.

8. The circuit of claim 6, wherein a threshold voltage of the third switch transistor is lower than that of the first switch transistor, and a threshold voltage of the fourth switch transistor is lower than that of the second switch transistor.

9. A phase locked loop (PLL) circuit, comprising:
the charge pump circuit of claim 1;
a phase detector configured to generate the first signal and the second signal and provide the first and second signals to the charge pump circuit;
a loop filter low-pass-filtering a voltage of the output node and generating a control voltage; and
a voltage controller oscillator (VCO) generating a feedback clock signal synchronized with a reference clock signal in response to the control voltage.

10. The circuit of claim 9, wherein the controller includes:
a third switch transistor controlling a portion of a current of a first current source, the first current source providing the first current, to flow to an internal node in response to the second signal;
a fourth switch transistor providing a portion of a current of a second current source, the second current source providing the second current, to the second current source in response to the first signal; and
a buffer including an input terminal connected to the output node and an output terminal connected to the internal node, the internal node positioned between the third and fourth switch transistors.

11. The circuit of claim 10, wherein a channel width of the third switch transistor is greater than that of the first switch transistor, and a channel width of the fourth switch transistor is greater than that of the second switch transistor.

12. The circuit of claim 10, wherein a threshold voltage of the third switch transistor is lower than that of the first switch transistor, and a threshold voltage of the fourth switch transistor is lower than that of the second switch transistor.

13. The circuit of claim 9, wherein the controller includes:
a third switch transistor controlling a portion of a current of a first current source, the first current source providing the first current, to the first current source in response to the second signal;
a fourth switch transistor providing a portion of a current of a second current source, the second current source providing the second current, to the second current source in response to the first signal.

14. The circuit of claim 13, wherein a channel width of the third switch transistor is greater than that of the first switch transistor, and a channel width of the fourth switch transistor is greater than that of the second switch transistor.

15. The circuit of claim 13, wherein a threshold voltage of the third switch transistor is lower than that of the first switch transistor, and a threshold voltage of the fourth switch transistor is lower than that of the second switch transistor.

16. A delay locked loop (DLL) circuit comprising:
the charge pump circuit of claim 1;
a phase detector configured to generate the first signal and the second signal and provided the first and second signals to the charge pump circuit;
a loop filter low-pass-filtering a voltage of the output node and generating a control voltage; and
a variable delay circuit delaying a reference clock signal in response to the control voltage and generating a feedback clock signal synchronized with the reference clock signal.

17. The circuit of claim 16, wherein the controller includes:
a third switch transistor controlling a portion of a current of a first current source, the first current source providing the first current, to flow to an internal node in response to the second signal;
a fourth switch transistor providing a portion of a current of a second current source, the second current source providing the second current, to the second current source in response to the first signal; and
a buffer including an input terminal connected to the output node and an output terminal connected to the internal node, the internal node positioned between the third and fourth switch transistors.

18. The circuit of claim 17, wherein a channel width of the third switch transistor is greater than that of the first switch transistor, and a channel width of the fourth switch transistor is greater than that of the second switch transistor.

19. The circuit of claim 17, wherein a threshold voltage of the third switch transistor is lower than that of the first switch transistor, and a threshold voltage of the fourth switch transistor is lower than that of the second switch transistor.

20. The circuit of claim 16, wherein the controller includes:
a third switch transistor controlling a portion of a current of a first current source, the first current source providing the first current, to the first current source in response to the second signal;
a fourth switch transistor providing a portion of a current of a second current source, the second current source providing the second current, to the second current source in response to the first signal.

21. The circuit of claim 20, wherein a channel width of the third switch transistor is greater than that of the first switch transistor, and a channel width of the fourth switch transistor is greater than that of the second switch transistor.

22. The circuit of claim 20, wherein a threshold voltage of the third switch transistor is lower than that of the first switch transistor, and a threshold voltage of the fourth switch transistor is lower than that of the second switch transistor.

23. A method of controlling current, comprising:
supplying a first current to an output node in response to a first signal to increase a level of current at the output node;
sinking a second current from the output node in response to a second signal to decrease a level of current at the output node; and
reducing an amount of the first and second currents if the first and second currents are generated concurrently.

24. A charge pump circuit performing the method of claim 23.
